(19) United States
(12) Patent Application Publication
(10) Pub. No.: US 2022/0013404 A1
(43) Pub. Date: Jan. 13, 2022

(54) METHOD OF MANUFACTURING SEMICONDUCTOR DEVICE

(71) Applicant: Tokyo Electron Limited, Tokyo (JP)

(72) Inventors: Kazuo KIBI, Tokyo (JP); Toshitake TSUDA, Tokyo (JP); Kenji SUZUKI, Nirasaki-shi (JP)

(21) Appl. No.: 17/448,608

(22) Filed: Sep. 23, 2021

Related U.S. Application Data
(63) Continuation of application No. PCT/JP2020/011323, filed on Mar. 16, 2020.

(30) Foreign Application Priority Data
Mar. 28, 2019 (JP) 2019-063800

(51) Int. Cl. H01L 21/768; H01L 27/108

(52) U.S. Cl. CPC H01L 21/76802; H01L 21/76865; H01L 21/76856; H01L 27/10844

(57) ABSTRACT

A method for example manufacturing a semiconductor device, which includes: forming a hole in a region of an insulating film laminated on a substrate; embedding a first conductive material in the hole to a position lower than a height of a sidewall of the hole; further embedding a second conductive material through a selective growth in the hole in which the first conductive material has been embedded; and etching the second conductive material to form a contact pad at a position above the hole.

### CROSS-REFERENCE TO RELATED APPLICATIONS

This application is a bypass continuation application of international application No. PCT/JP2020/011323 having an international filing date of Mar. 16, 2020 and designating the United States, the international application being based upon and claiming the benefit of priority from Japanese Patent Application No. 2019-063800, filed on Mar. 28, 2019, the entire contents of which are incorporated herein by reference.

### TECHNICAL FIELD

Various aspects and embodiments of the present disclosure relate to a method of manufacturing a semiconductor device.

### BACKGROUND

For example, Patent Document 1 below discloses forming a contact pad on a contact plug for connecting a capacitor and a diffusion layer to each other in a process of manufacturing a semiconductor device such as a dynamic random access memory (DRAM). The contact pad is laminated on the contact plug on which a barrier film is laminated. The contact pad may absorb the misalignment between the capacitor and the contact plug.

### PRIOR ART DOCUMENTS

### Patent Document

Patent Document 1: U.S. Patent Application Publication No. 2018/0040561

### SUMMARY

According to one embodiment of the present disclosure, there is provided a method of a semiconductor device, which includes: forming a hole in a region of an insulating film laminated on a substrate; embedding a first conductive material in the hole to a position lower than a height of a sidewall of the hole; further embedding a second conductive material through a selective growth in the hole in which the first conductive material has been embedded; and etching the second conductive material to form a contact pad at a position above the hole.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a flowchart illustrating an example of a semiconductor device manufacturing method according to an embodiment of the present disclosure.

FIG. 2A is a top view illustrating an example of a wafer used for manufacturing a semiconductor device according to an embodiment of the present disclosure, and FIG. 2B is a cross-sectional view taken along line A-A in the wafer illustrated in FIG. 2A.

FIG. 3A is a top view illustrating an example of the wafer in which insulating films are embedded, and FIG. 3B is a cross-sectional view taken along line A-A in the wafer illustrated in FIG. 3A.

FIG. 4 is a top view illustrating an example of the wafer on which a mask film having a predetermined pattern is laminated.

FIG. 5 is a top view illustrating an example of the wafer in which holes are formed.

FIG. 6A is a top view illustrating an example of the wafer in which contact plugs are formed in the holes, and FIG. 6B is a cross-sectional view taken along line A-A in the wafer illustrated in FIG. 6A.

FIG. 7A is a top view illustrating an example of the wafer in which a second conductive material is embedded in the holes, and FIG. 7B is a cross-sectional view taken along line A-A in the wafer illustrated in FIG. 7A.

FIG. 8A is a top view illustrating an example of the wafer in which contact pads are formed, and FIG. 8B is a cross-sectional view taken along line A-A in the wafer illustrated in FIG. 8A.

FIG. 9A is a top view illustrating an example of a wafer in a comparative example in which a base film is formed, and FIG. 9B is a cross-sectional view taken along line A-A in the wafer illustrated in FIG. 9A.

FIG. 10A is a top view illustrating an example of the wafer in the comparative example in which a barrier film is laminated, and FIG. 10B is a cross-sectional view taken along line A-A in the wafer illustrated in FIG. 10A.

FIG. 11A is a top view illustrating an example of the wafer in the comparative example in which a second conductive material is embedded, and FIG. 11B is a cross-sectional view taken along line A-A in the wafer illustrated in FIG. 11A.

FIG. 12A is a top view illustrating an example of the wafer in the comparative example in which contact pads are formed, and FIG. 12B is a cross-sectional view taken along line A-A in the wafer illustrated in FIG. 12A.

FIGS. 13A and 13B are schematic views each for explaining an example of a size of crystal grains in a lower portion of a contact pad.

### DETAILED DESCRIPTION

Hereinafter, embodiments of a semiconductor device manufacturing method disclosed herein will be described in detail with reference to the drawings. The semiconductor device manufacturing method disclosed herein is not limited by the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a conventional method of manufacturing contact pads of a semiconductor device such as DRAM, in holes surrounded by an insulating member, a base film of a cobalt silicide or the like is formed on contact plugs exposed on the bottoms of the holes, respectively. Then, a barrier film of a titanium nitride or the like is laminated on the base film and the sidewalls of the holes. Then, contact pads are formed by embedding a conductive material in the holes covered with the barrier film.

With the recent increase in the density of semiconductor devices, the width of the contact pads tends to become narrower, and thus the resistance value of the contact pads tends to increase. When the resistance value of the contact pads increases, the delay of signals flowing through the contact plugs may increase, and the heat generation and power consumption of the semiconductor devices may increase.

### [Semiconductor Device Manufacturing Method]

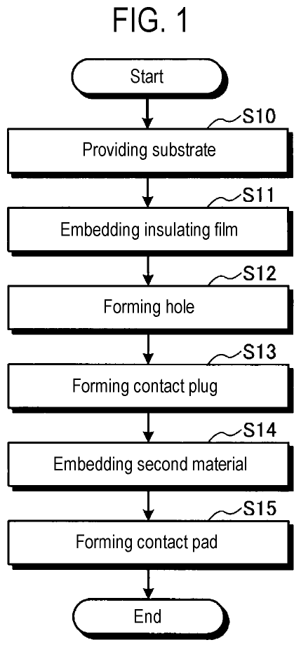

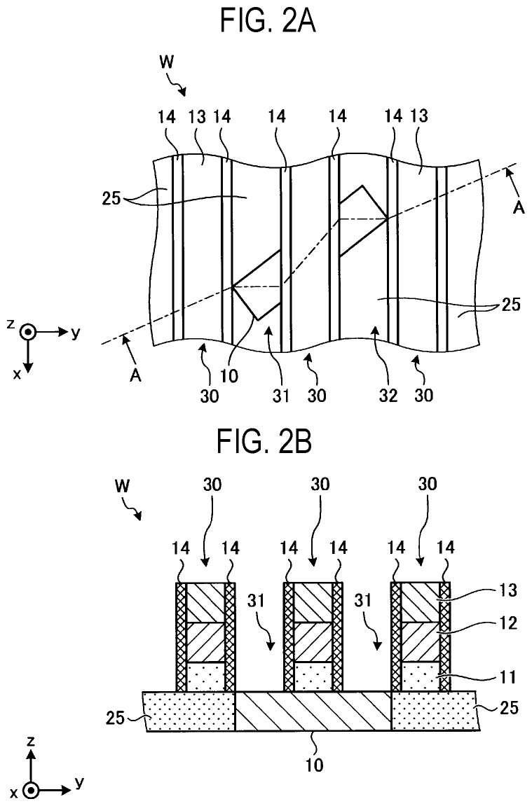

FIG. 1 is a flowchart illustrating an example of a semiconductor device manufacturing method according to an embodiment of the present disclosure. In the present embodiment, a wafer W used for manufacturing a semiconductor device is manufactured through a procedure illustrated in the flowchart of FIG. 1. Hereinafter, an example of the semiconductor device manufacturing method will be described with reference to FIGS. 2A to 8B.

First, the wafer W to be processed is provided (S10). The wafer W to be processed has, for example, a structure as illustrated in FIGS. 2A and 2B. FIG. 2A is a top view illustrating an example of the wafer W used for manufacturing the semiconductor device according to an embodiment of the present disclosure, and FIG. 2B is a cross-sectional view taken along line A-A in FIG. 2A.

For example, the wafer W illustrated in FIGS. 2A and 2B has an active region 10, which is formed of a semiconductor, such as silicon, into which a p-type impurity is introduced, and insulating regions 25 made of, for example, a silicon oxide. A member including the active region 10 and the insulating regions 25 is an example of a substrate. Contacts 11 made of a polycrystalline silicon or the like are formed on the surfaces of the active region 10 and the insulating regions 25. An electrode film 12 of tungsten or the like is laminated on each contact 11. An insulating film 13 such as a silicon nitride or the like is laminated on each electrode film 12.

Each of the side surfaces of the contacts 11, the electrode films 12, and the insulating films 13 is covered with a spacer 14. The spacer 14 has, for example, a structure in which a silicon oxide film is sandwiched between silicon nitride films. For example, as illustrated in FIGS. 2A and 2B, structures 30, each having the contact 11, the electrode film 12, and the insulating film 13 covered with the spacer 14, are arranged at a predetermined interval in the y-axis direction. Each structure 30 extends in the x-axis direction. Further, a groove 31 is formed between the structures 30 adjacent to each other in the y-axis direction.

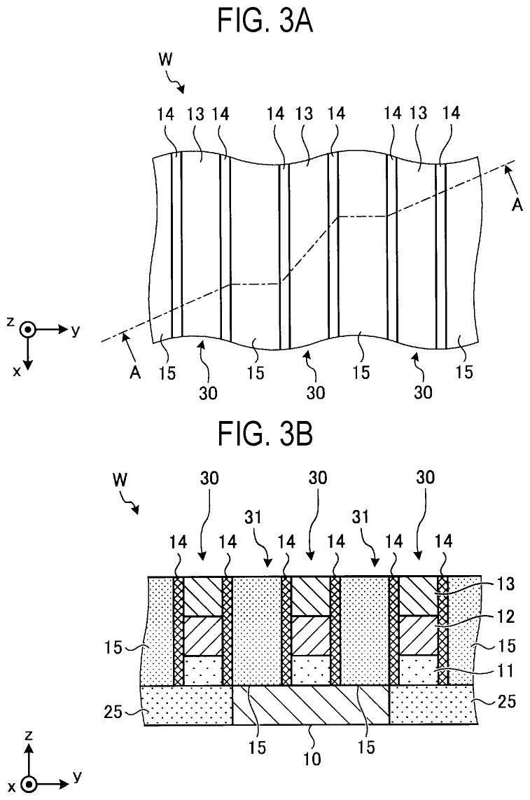

Subsequently, the insulating film 15 is embedded in the groove 31 (S11). The insulating film 15 is formed of, for example, a silicon oxide. Then, an excess insulating film 15 is removed through chemical mechanical polishing (CMP) or the like. This brings the wafer W into, for example, the state illustrated in FIGS. 3A and 3B. FIG. 3A is a top view illustrating an example of the wafer W in which insulating films 15 are embedded, and FIG. 3B is a cross-sectional view taken along line A-A in FIG. 3A.

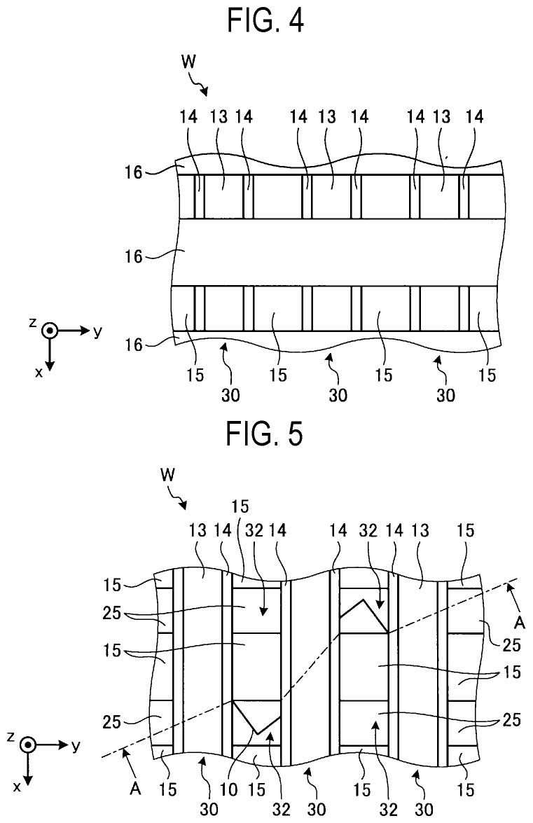

Subsequently, the insulating films 15 in the grooves 31 are removed along a mask pattern, so that holes 32 are formed (S12). Step S12 is an example of a hole forming step. For example, a mask film 16 is laminated on the wafer W, and the mask film 16 is processed to have a predetermined pattern through photolithography, for example, as illustrated in FIG. 4. FIG. 4 is a top view illustrating an example of the wafer W on which the mask film 16 having the predetermined pattern is laminated.

Then, the insulating films 15 in the grooves 31 are removed along the mask pattern through dry etching, so that holes 32 are formed. Thereafter, the mask film 16 is removed. This brings the wafer W into, for example, the state illustrated in FIG. 5. FIG. 5 is a top view illustrating an example of the wafer W in which the holes 32 are formed. The cross section of line A1-A1 in FIG. 5 is similar to that of FIG. 3B. The cross section of line A2-A2 in FIG. 5 is similar to that in FIG. 2B. This causes the holes 32, each surrounded by the spacers 14 and the insulating films 15, to be formed on the wafer W.

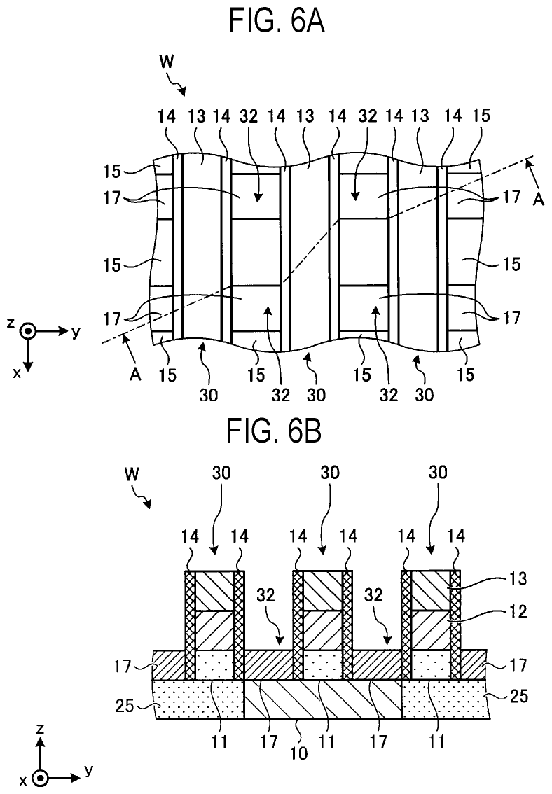

Subsequently, by embedding a first conductive material in the holes 32, contact plugs 17 are formed in the holes 32 (S13). Step S13 is an example of a first embedding step. The first conductive material is, for example, a polysilicon. In step S13, the first conductive material is embedded to a position lower than the height of the sidewalls forming the holes 32. This brings the wafer W into, for example, the state illustrated in FIGS. 6A and 6B. FIG. 6A is a top view illustrating an example of the wafer W in which the contact plugs 17 are formed in the holes 32, and FIG. 6B is a cross-sectional view taken along line A-A in FIG. 6A.

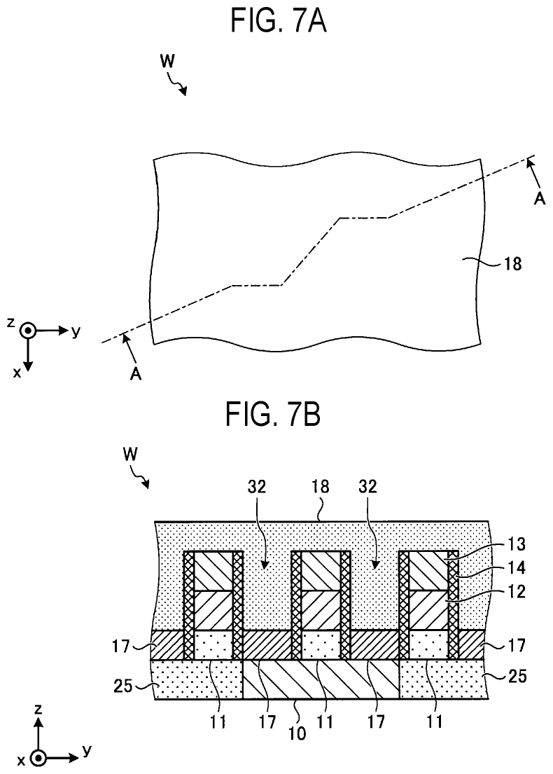

Subsequently, a second conductive material 18 is embedded through selective growth in the holes 32 in which the first conductive material is embedded (S14). Step S14 is an example of a second embedding step. The second conductive material 18 is, for example, tungsten. This causes the second conductive material 18 to be embedded in the holes 32, for example, as illustrated in FIGS. 7A and 7B. FIG. 7A is a top view illustrating an example of the wafer W in which the second conductive material 18 is embedded in the holes 32, and FIG. 7B is a cross-sectional view taken along line A-A in FIG. 7A.

In step S14, the second conductive material 18 is laminated in the holes 32 through selective growth. In the selective growth, the second conductive material 18, such as tungsten, grows on the contact plugs 17 made of a polysilicon or the like, but the second conductive material 18 does not grow on the insulating films 13, such as silicon nitride films, and the spacers 14, each including a silicon oxide film and a silicon nitride film. After the second conductive material 18 is embedded in the holes 32, the second conductive material 18 also grows in a plane direction above the holes 32. For example, as illustrated in FIGS. 7A and 7B, the second conductive material 18 is also formed in regions overlapping the insulating films 13 and the spacers 14, which are regions outside the holes 32. The film thickness of the second conductive material 18 in the regions overlapping the insulating films 13 and the spacers 14 is smaller than that of the second conductive material 18 in the regions overlapping the holes 32.

In the selective growth, since the second conductive material 18 does not grow on the insulating films 13 and the spacers 14, the tungsten atoms inside the second conductive material 18 do not reach the insulating films 13 and the spacers 14. This prevents metal contamination in which tungsten atoms infiltrates into the insulating films 13 and the spacers 14. Therefore, it is not necessary to interpose a barrier film for preventing metal contamination by tungsten atoms between the second conductive material 18 and the spacers 14.

The second conductive material 18 is selectively laminated in the holes 32 through, for example, a method of alternately repeating chemical vapor deposition (CVD) and dry etching using plasma. In the CVD, for example, by supplying a tungsten-containing gas to the surface of the wafer W, tungsten is laminated on the surface of the wafer W including the interiors of the holes 32. In the dry etching, for example, by supplying plasma of a hydrogen-containing gas to the surface of the wafer W, a portion of the tungsten laminated on the surface of the wafer W is etched.

For example, the temperature of the wafer W is controlled to 450 degrees C. to 550 degrees C., the CVD using WCl₅ gas is executed for a predetermined period of time, and then the dry etching using plasma of a H₂ gas is executed for a predetermined period of time. An amount of the WCl₅ gas supplied in the CVD is, for example, 50 to 500 mg/min. A flow rate of the H₂ gas in the dry etching is, for example, 1,000 to 9,000 sccm. A time period of one cycle including one round of CVD and one round of dry etching is, for example, 0.2 seconds to 10 seconds. A ratio of the CVD period to the dry etching period in one cycle is, for example, 1:1. In the lamination of the second conductive material 18 of the present embodiment, the cycle including one round of CVD and one round of dry etching is repeated, for example, about several hundred times.

As the raw material gas used in the CVD, a WCl₆ gas, a WF₆ gas, or the like may be used instead of the WCl₅ gas. In addition, as the etching gas used in the dry etching, a SiH₄ gas or the like may be used instead of the H₂ gas. In addition, as the plasma source used in the dry etching, for example, capacitively coupled plasma (CCP), inductively coupled plasma (ICP), microwave excitation surface wave plasma (SWP), electron cyclotron resonance plasma (ECRP), or helicon wave excitation plasma (HWP), may be used.

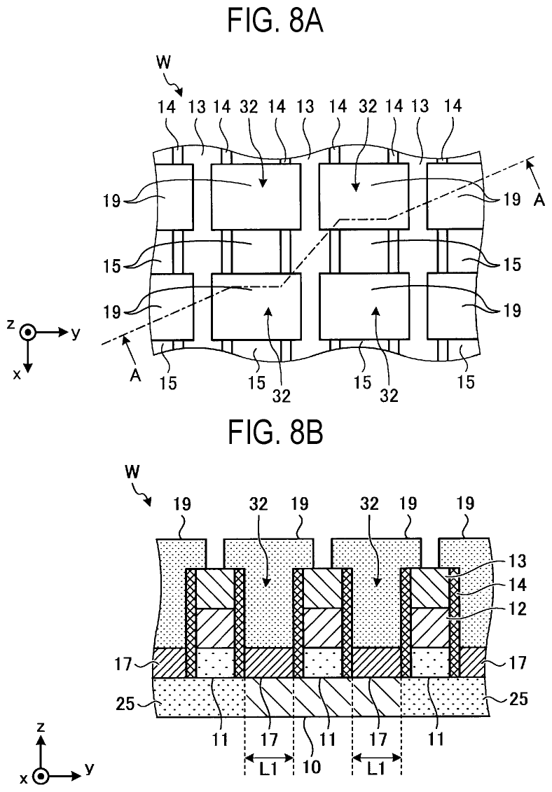

Subsequently, by processing the second conductive material 18 above the holes 32 through dry etching or the like, contact pads 19 are formed above the holes 32 (S15). This brings the wafer W into, for example, the state illustrated in FIGS. 8A and 8B. FIG. 8A is a top view illustrating an example of the wafer W in which the contact pads 19 are formed, and FIG. 8B is a cross-sectional view taken along line A-A in FIG. 8A.

### Comparative Example

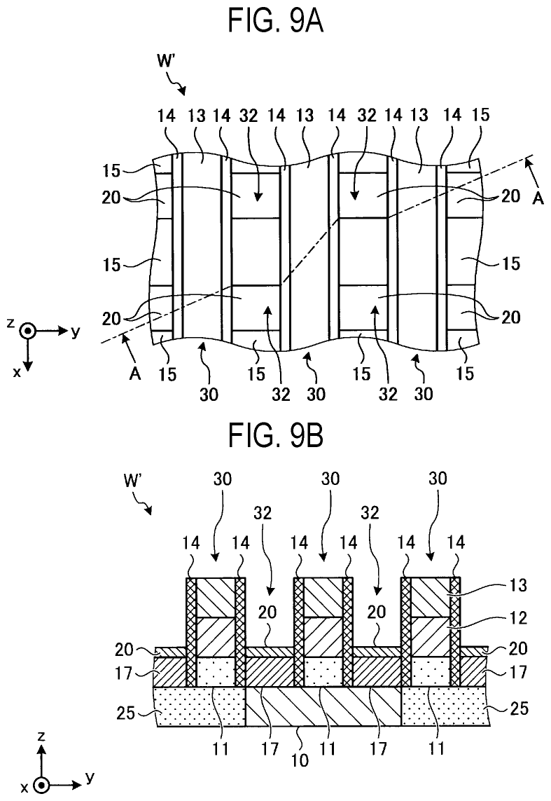

Next, a procedure for manufacturing a semiconductor device in a comparative example will be described with reference to FIGS. 9A to 12B. In the manufacturing procedure of the semiconductor device in the comparative example, the same processing as in steps S10 to S13 in the above-described embodiment is performed. That is, up to the state illustrated in FIGS. 6A and 6B, the manufacturing procedure of the semiconductor device in the comparative example is the same as the manufacturing procedure of the semiconductor device in the embodiment.

In the comparative example, base films 20 are formed in the holes 32. The base films 20 are formed of, for example, a cobalt silicide. This brings a wafer W′ into, for example, the state illustrated in FIGS. 9A and 9B. FIG. 9A is a top view illustrating an example of the wafer W′ in which the base films 20 are embedded, and FIG. 9B is a cross-sectional view taken along line A-A in FIG. 9A.

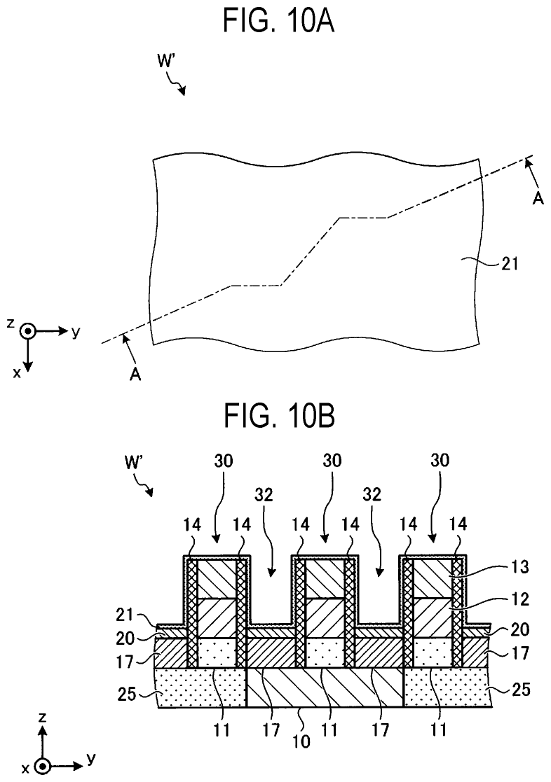

Subsequently, a barrier film 21 is laminated on the entire wafer W′. The barrier film 21 is formed of, for example, a titanium nitride. This brings the wafer W′ into, for example, the state illustrated in FIGS. 10A and 10B. FIG. 10A is a top view illustrating an example of the wafer W′ on which the barrier film 21 is formed, and FIG. 10B is a cross-sectional view taken along line A-A in FIG. 10A.

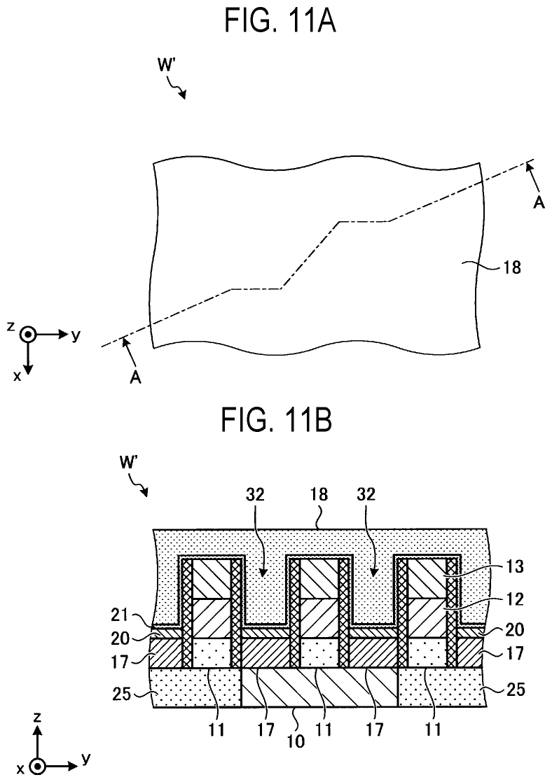

Subsequently, a second conductive material 18 is embedded in the holes 32. The second conductive material 18 is, for example, tungsten. In the comparative example, the second conductive material 18 is laminated in the holes 32 through CVD or atomic layer deposition (ALD). This brings the wafer W′ into, for example, the state illustrated in FIGS. 11A and 11B. FIG. 11A is a top view illustrating an example of the wafer W′ in the comparative example in which the second conductive material 18 is embedded, and FIG. 11B is a cross-sectional view taken along line A-A in 11A.

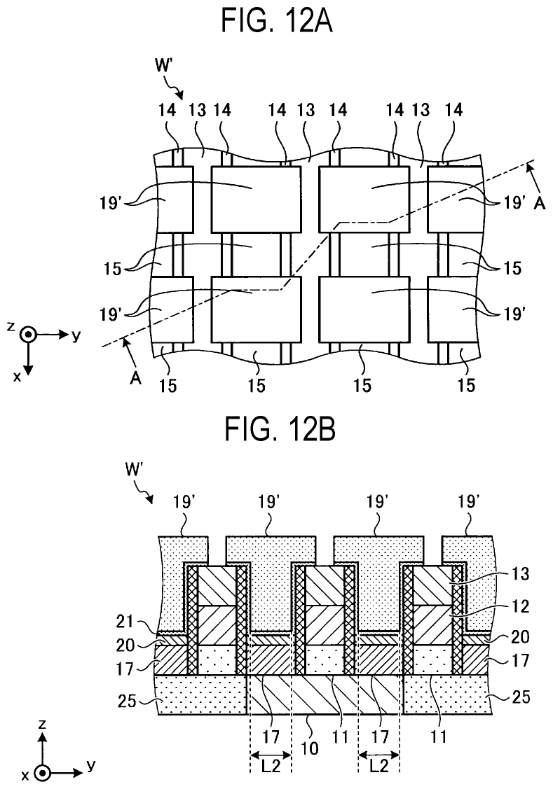

Thereafter, by processing the second conductive material 18 above the holes 32 through dry etching or the like, contact pads 19′ are formed. This brings the wafer W′ into, for example, the state illustrated in FIGS. 12A and 12B. FIG. 12A is a top view illustrating an example of the wafer W′ in the comparative example in which the contact pads 19′ are formed, and FIG. 12B is a cross-sectional view taken along line A-A in FIG. 12A.

Here, a resistance value at an interface where different metals come into contact with each other is larger than that of a single bulk metal. In the comparative example, a base film 20 and a barrier film 21 are interposed between each contact plug 17 and each contact pad 19′, for example, as illustrated in FIG. 12B. Therefore, an interface resistance exists at each of the interface between the contact plug 17 and the base film 20, the interface between the base film 20 and the barrier film 21, and the interface between the barrier film 21 and the contact pad 19′. This causes the resistance value between the contact plug 17 and the contact pad 19′ to increase in the comparative example. When the resistance value between the contact plug 17 and the contact pad 19′ increases, the delay of signals flowing through the contact plug may increase, and the heat generation and power consumption of the semiconductor device may increase.

In contrast, in the present embodiment, for example, as illustrated in FIG. 8B, the second conductive material 18 to be turned into the contact pads 19 is laminated on each contact plug 17. Therefore, there is an interface resistance at the interface between each contact plug 17 and each contact pad 19. However, the number of interfaces interposed between the contact plugs 17 and the contact pads 19 is smaller than that in the comparative example. Therefore, in the present embodiment, the resistance value between the contact plugs 17 and the contact pads 19 can be reduced.

In addition, in the comparative example, the width of the contact pad 19′ in each hole 32 is L2 which is smaller than the width of the hole 32 by the thickness of the barrier film 21, for example, as illustrated in FIG. 12B. Meanwhile, in the present embodiment, the width of the contact pad 19 in each hole 32 is L1 which is substantially the same as the width of the hole 32, for example, as illustrated in FIG. 8B. As described above, in the present embodiment, since no barrier film 21 is provided, the width of the contact pad 19 in each hole 32 is larger than the width of the contact pad 19′ in the comparative example. Therefore, the resistance value of the contact pad 19 of the present embodiment is lower than the resistance value of the contact pad 19′ in the comparative example.

### [Size of Crystal Grains in Conductive Material]

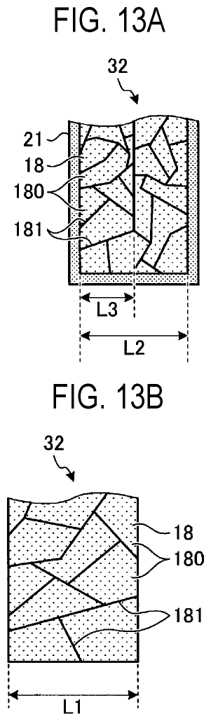

FIGS. 13A and 13B are schematic views each for explaining an example of the size of crystal grains 180 at a lower portion of a contact pad. FIG. 13A illustrates an example of the size of crystal grains 180 in the comparative example, and FIG. 13B illustrates an example of the size of crystal grains 180 in the present embodiment.

In the comparative example, the crystal grains 180 grown from the bottom of the hole 32 grow within the range of the width L2 of the hole 32, for example, as illustrated in FIG. 13A. Meanwhile, in the present embodiment, the crystal grains 180 grown from the bottom of the hole 32 grow within the range of the width L1 of the hole 32, for example, as illustrated in FIG. 13B. Therefore, the crystal grains 180 in the present embodiment can grow larger than the crystal grains 180 in the comparative example.

In addition, in the comparative example, since the second conductive material 18 is laminated through CVD or ALD, the nuclei of the second conductive material 18 are formed on the barrier film 21, and the nuclei grow to become the crystal grains 180. The nuclei of the second conductive material 18 are formed not only on the barrier film 21 on the bottom surface of the hole 32, but also on the barrier film 21 on the sidewall of the hole 32, and the crystal grains 180 also grow on the sidewall of the hole 32. The crystal grains 180 grown from the opposite sidewalls of the hole 32 stop growing in the center of the hole 32, for example, as illustrated in FIG. 13A. Therefore, in the comparative example, the crystal grains 180 grown from the sidewall of the hole 32 grow only within the range of the width L3, which is about half the width L2 of the hole 32.

In contrast, in the present embodiment, since the second conductive material 18 is laminated in the hole 32 through the selective growth, the nuclei of the second conductive material 18 do not grow on the spacer 14 constituting the sidewall of the hole 32. Therefore, the crystal grains 180 of the second conductive material 18 are able to grow from the bottom of the hole 32 within the range of the width L1 of the hole 32. This makes it possible for the crystal grains 180 in the present embodiment to grow to be larger than the crystal grains 180 in the comparative example.

Here, the resistance value becomes large at the interfaces 181 between adjacent crystal grains 180. Therefore, in order to reduce the resistance value, it is preferable to increase the crystal grains 180 to reduce the number of interfaces 181. In the present embodiment, it is possible to grow the crystal grains 180 to be larger than those in the comparative example. Therefore, in the present embodiment, it is possible to lower the resistance value of the contact pad 19 compared with that in the comparative example.

In the foregoing, the embodiments have been described. As described above, the semiconductor device manufacturing method according to the present embodiment includes the hole forming step, the first embedding step, the second embedding step, and the etching step. In the hole forming step, the holes 32 are formed in the region of the insulating film 15 laminated on the substrate. In the first embedding step, the first conductive material is embedded in the holes 32 to a position lower than the height of the sidewall forming the holes 32. In the second embedding step, the second conductive material 18 is further embedded in the holes 32 in which the first conductive material is embedded through the selective growth. In the etching step, the contact pads 19 are formed at respective positions above the holes 32 by etching the holes 32. This makes it possible to reduce the resistance value of the contact pads 19.

In addition, in the above-described embodiments, the first conductive material is polysilicon, and the second conductive material 18 is tungsten. As a result, the contact pad can be formed on the second conductive material 18.

In the above-described embodiments, in the second embedding step, a step of supplying a tungsten-containing gas to the surface of the substrate and a step of supplying the plasma of a hydrogen-containing gas to the surface of the substrate are alternately repeated. This makes it possible to easily form the contact pads 19 on the respective contact plugs 17.

In addition, in the embodiments described above, the tungsten-containing gas is the WCl₅ gas, the WCl₆ gas, or the WF₆ gas, and the hydrogen-containing gas is the H₂ gas or the SiH₄ gas. This makes it possible to selectively grow the second conductive material 18 on the contact plugs 17.

According to various aspects and embodiments of the present disclosure, it is possible to reduce a resistance value of a contact pad.

It should be understood that the embodiments disclosed herein are exemplary in all respects and are not restrictive. Indeed, the above-described embodiments can be implemented in various forms. The embodiments described above may be omitted, replaced, or modified in various forms without departing from the scope and spirit of the appended claims.

What is claimed is:

1. A method of manufacturing a semiconductor device, the method comprising:
forming a hole in a region of an insulating film laminated on a substrate;
embedding a first conductive material in the hole at a position lower than a height of a sidewall of the hole;
further embedding a second conductive material through a selective growth in the hole in which the first conductive material has been embedded; and
etching the second conductive material to form a contact pad at a position above the hole.

2. The method of claim 1, wherein the first conductive material is a polysilicon, and the second conductive material is tungsten.

3. The method of claim 1, wherein the embedding the second conductive material includes alternately repeating supplying a tungsten-containing gas to a surface of the substrate and supplying plasma of a hydrogen-containing gas to the surface of the substrate.

4. The method of claim 3, wherein the tungsten-containing gas is a WCl₅ gas, a WCl₆ gas, or a WF₆ gas, and the hydrogen-containing gas is a H₂ gas or a SiH₄ gas.

5. A method of manufacturing a semiconductor device, the method comprising:
embedding a groove between spacers formed on a substrate with an insulating film;
forming a hole surrounded by the spacers and the insulating film by removing a portion of the insulating film;
forming a first conductive material in the hole at a position lower than a height of a sidewall constituting the hole;
forming a second conductive material on the first conductive material; and
removing a portion of the second conductive material to form a contact pad at a position above the hole,
wherein the second conductive material is not formed on the insulating film and the spacers before the hole is embedded with the first conductive material, and is formed on the insulating film and the spacers after the hole is completely embedded with the first conductive material.

6. The method of claim 5, wherein the first conductive material is a polysilicon, and the second conductive material is tungsten.
